(19) United States
(12) Patent Application Publication
(10) Pub. No.: US 2001/0050561 A1
(43) Pub. Date: Dec. 13, 2001

(54) Capacity testing method and arrangement

(76) Inventor: Kjell Rundkvist, Lidingo (SE)

Correspondence Address: Harness, Dickey & Pierce, P.L.C., P.O. Box 828, Bloomfield Hills, MI, 48303, US

(21) Appl. No.: 09/726,201

(22) Filed: Nov. 29, 2000

(30) Foreign Application Priority Data
Dec. 3, 1999 (SE) 9904403-4

(51) Int. Cl. G01R 27/26

(52) U.S. Cl. 324/678

(57) ABSTRACT

A method and an arrangement of in-circuit capacity testing of at least one stand-by electrical energy storage device (1; 11; 12) connected between two conductors (3, 4; 13, 14) in parallel with a DC supply, in turn supplied from a mains line, and also in parallel with a power consuming device (2) is described. A controllable current source (6) is provided that is connectable in series with the battery (1). A control device (7) controls the controllable current source (6) to maintain either a desired output current or a desired output power from the battery (1). A voltage measuring device (8) for measures the voltage across the battery (1) to determine its capacity at least during testing.

### TECHNICAL FIELD

The invention relates generally to electrical energy storage devices, and more specifically to a method and an arrangement for capacity testing of such devices.

### BACKGROUND OF THE INVENTION

In modern electrical energy storage devices, such as valve-regulated lead acid (VRLA) batteries it is not possible due to design reasons to measure the acid density in order to get an idea about the capacity of the battery. Such batteries are often provided as stand-by batteries in base stations for mobile telephone systems.

It is important that the stand-by battery (-ies) are well-functional, such that one can depend upon that they take over to supply the load as long as needed. Therefore, it is necessary to check each battery from time to time both if it is charged to full capacity and to prove that it has not aged too much and need to be exchanged for a new one. A criterion for exchanging a battery is that its capacity has decreased to 80% of the capacity it had when it was new. Within the technical field of telephony there are very high demands on accessibility. Failures are not allowed because the whole system must function, particularly at situations of distress.

A discharge check down to lower voltage limit should demand that the battery is disconnected from the circuitry during the check, and an artificial controllable load is provided across the battery. The battery supplier most often recommends a discharge time of 10 or 20 h using the nominal discharge current of the battery. At least two persons must be sent to the station in order to provide this discharge, since one person is forbidden to do this kind of work alone. A problem of having an artificial load is that it must consume considerable amount of energy, which means that it will be very hot. The heat so generated must be ventilated to the surroundings.

### DESCRIPTION OF RELATED ART

It is therefore a need to make such a discharge test in a more simple way and in a shorter time. There have earlier been many tries in this respect. A common feature for them all have been that they have not been able to provide an exact result.

In-circuit discharge tests of stand-by batteries have become popular. In connection with central office operations, it is quite common to carry out discharge tests on stand-by batteries by passivating the charging rectifiers and letting the central office constitute the load.

A standard method within the telecom technique in this respect has been to let the battery be maintained parallel to the AC/DC supply in the supply circuit to the load. At check the voltage across the AC/DC supply is lowered to such a low level that the battery takes over the supply of the load. The load could then be the switchboard in a base station for mobile telephone systems. Thereafter, a check is done of how fast the voltage across the battery is decreasing. However, the switchboard has a different and also varying current need. An instant calculation of the ratio between the voltage and the output current during the monitoring time is rather complicated. It is dependent on the different kind of batteries, and the individual variations of batteries of the same kind. Thus, a number of data regarding the individual battery to be checked must be provided. Therefore, earlier measurements having the battery connected to the load during battery check have not been exact. Also, the lowering of the voltage across the AC/DC supply is something, which one wishes to avoid.

This method has several disadvantages. Most often, the tests are carried out in the night, when the load is low, which means that time-criteria do not give any correct information about the remaining capacity. For safety reasons, the batteries are not discharged to more than 50%, which means that the remaining capacity has to be estimated. This introduces considerable insecurity. Moreover, a central office has a varying load characteristic, which makes it difficult to relate the measurements to discharge graphs provided by the battery manufacturers.

U.S. Pat. No. 5,416,403 describes method, which implies that some kind of varying square AC current superimposed on a direct current is provided through the battery. The battery used according to the U.S. Pat. No. 5,416,403 is not normally provided parallel to a voltage supply fed from the mains, but is adapted to be the normal voltage supply for the load. The voltage across the battery is measured. This means that it is important to know the data of the actual battery in order to have an exactly right result. U.S. Pat. No. 5,416,403 describes an impedance measuring examination. In accordance with the U.S. Pat. No. 5,416,403 the battery is connected as a source. The load is typically some kind of transportable computer or the like. When a check of the battery is to be made, an inductor is connected between the battery and the load. The load can consume varying current in time during a test dependent upon its current work. The circuitry between the battery and the load is a kind of filter, which stabilises the current between the battery and the load. The circuitry of this kind could not maintain a constant current to the load, i.e. it can not maintain a constant DC supply level for the load. It can only delete the short time variations coming from the load.

### SUMMARY OF THE INVENTION

The object of the invention is to bring about a simple method and a simple arrangement for in-circuit capacity testing of stand-by electrical energy storage devices, such as modem VRLA-batteries.

The invention relates to a method and an arrangement of in-circuit capacity testing of at least one stand-by electrical energy storage device connected between two conductors in parallel with a DC supply, in turn supplied from a mains line, and also in parallel with a power consuming device. The invention is characterized by during a test operation for one said electrical energy storage device a controllable current source is provided in series with the electrical energy storage device between the two conductors. The controllable current source is controlled to maintain either a desired output current or a desired output power from the electrical energy storage device. The voltage across the electrical energy storage device is measured. The capacity of the electrical energy storage device is determined in dependence on measured voltages across the electrical energy storage device.

The controllable current source could be controlled to maintain either a constant output current or a constant output power from the electrical energy storage device during a test operation. The controllable current source is preferably chosen such that the voltage across it together with the voltage across the electrical energy storage device during control during battery check is higher than the voltage across the DC supply supplied from the mains line.

By controlling the current source such that the battery is discharged in correspondence with the graphs provided by the manufacturer, a clear picture of the actual capacity of the battery will be obtained.

The invention lies in the fact that instead of lowering the voltage across the voltage supply from the mains an electronic current supply is provided in series with the battery to be checked. The current supply is controlled to give a constant current or effect during a check procedure. This will increase the voltage provided across the battery together with the current supply to such an extent that the contribution of the DC voltage supply from the mains is brought to a minimum. It is to be noted that the DC voltage supply under normal conditions, i.e. when no battery check is performed, is adjusted to provide a constant voltage to bus bars, to which the load is connected, independent upon the requested current need, as distinguished from the conditions during battery test.

Each stand-by battery is connected between the current bars just as the voltage supply from the mains and the load. There are often at least two batteries in the circuit, so that one can be sure of that at least one will be functional if the mains supply should fail.

### ADVANTAGE

A great advantage of the invention is that it provides capacity according to the data sheet of each monitored battery. Only the circuit, in which the battery is connected and controlled, is amended. There are no changes made of the voltage supply from the mains and of the load. No extra elements are inserted between the battery and the load except for the controlled current source.

### BRIEF DESCRIPTION OF THE DRAWINGS

For a more complete understanding of the present invention and for further objects and advantages thereof, reference is now made to the following description of examples of embodiments thereof—as shown in the accompanying drawings, in which:

FIG. 1 schematically illustrates a first embodiment of an arrangement in accordance with the invention for in-circuit capacity testing of a battery; and

FIG. 2 schematically illustrates a second embodiment of an arrangement in accordance with the invention for in-circuit capacity testing of a battery.

### DESCRIPTION OF THE PREFERRED EMBODIMENTS

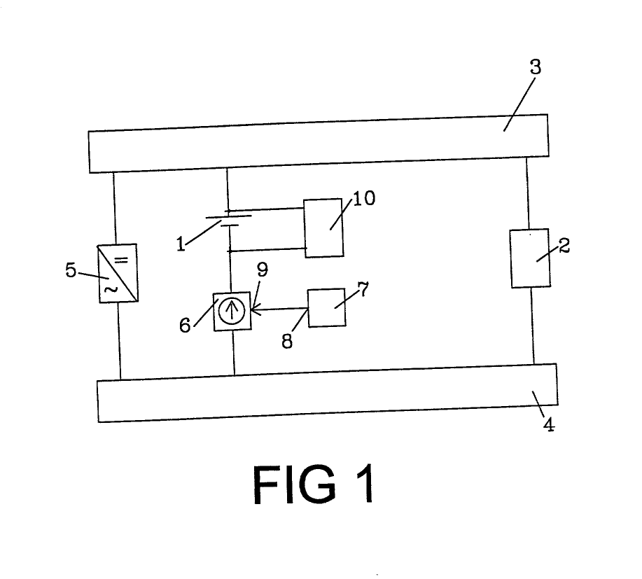

Referring to FIG. 1, a first embodiment of the invention for in-circuit capacity at least one stand-by electrical energy storage device 1, below called battery, is connected in parallel to the load 2 between conductors, such as bus bars 3, 4. The parallel coupling is supplied by a schematically indicated DC supply 5, in turn supplied from a mains line, i.e. a rectifier supply 5 connected to the mains line in order to provide the normal DC supply for the base station. Each stand-by battery is kept loaded from the DC supply 5 and is only to be used as a supply voltage for the load at mains failure.

According to the invention means are provided for testing the stand-by battery 1 while it is connected to the load 2. The load is for example a telephone exchange. It is to be noted that the invention is not limited to a voltage supply for a telephone exchange but could also be provided for every kind of equipment, which need a continuous DC supply secured against mains failure.

It is to be understood that there can be more than one stand-by battery and also more than one rectifier supply connected in parallel between the bus bars 3,4.

In accordance with the invention, to in-circuit test the capacity of the battery 1, a controllable current source 6 is connected in series with the battery 1 between the bus bars 3, 4.

A control device 7 is connected with an output 8 to a control input of the controllable current source 6. It needs a supply of energy, because when the battery begins to be discharged, then the switchboard is used as the load 2. The switchboard is normally driven from the rectifier supply 5. Then, the rectifier supply 5 is adjusted to supply a constant voltage between the bus bars 3, 4, independent upon the current need. However, when the battery should be checked the battery voltage together with the voltage across the current source 6 is chosen to be so high that the switchboard will be driven to a great extent from the battery to be checked. When the current source drives the discharge current through the battery out on the bus bars 3, 4, the current is closed through the load 2. The DC supply will then lower its output current in the same extent, so that the voltage across the bus bars 3 and 4 is kept constant. It is important, for providing correct function, that the load 2 consumes at least as much current as the current source 6 delivers. The characteristic feature of a current source is that it, at least theoretically, drives its current independently of the voltage arising across it.

Thus, the battery is discharged through the switchboard by means of the current source 6. The electronic circuitry inside the current source 6 is adjusted by the control device 7 to maintain either a desired output current through the battery, or alternatively a desired output power from the battery. Preferably, the current source 6 is controlled by the control device 7 to maintain the output current or the output power constant during a check procedure.

However, when the controllable current source 6 is in idle condition, i.e. not controlled by the control circuit 7, the current source 6, functioning as a diode, the voltage across the battery together with the source is lower than the voltage across the rectifier supply 5. Then the load is supplied from the rectifier supply 5 and not from the battery 1.

At least while the current from the controllable current source 6 is controlled by means of the control device 7, a voltage-measuring device 10 is connected across the battery 1 to measure or monitor the battery voltage.

By means of the voltage-measuring device 10, the voltage across the battery 1 could thus be measured at different times or monitored and recorded for longer time periods.

The capacity of the battery 1 can be determined, e.g. by checking after a predetermined time interval, e.g. 10 hours, whether the battery has been discharged to a voltage above or below a predetermined threshold value.

If the battery voltage is below that threshold value, the battery should be replaced.

If the voltage of just a single battery cell is found to be below a threshold value, just that single battery cell should be replaced.

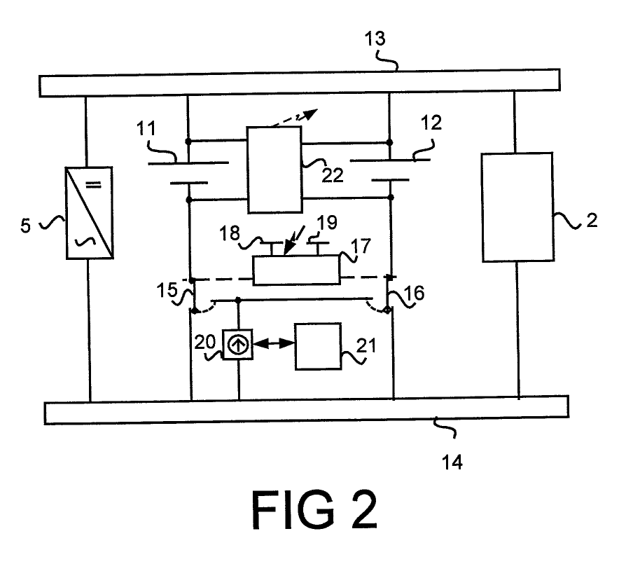

Referring to FIG. 2, two batteries 11 and 12 are connected between the bus bars 13, 14. Naturally, more than two batteries could be provided and controlled according to the same principles as the two batteries illustrated in FIG. 2. Only one of the batteries will be checked at the time. Normally, the battery 11 will be connected to the negative bus bar 4 through a controllable normally closed switch 15, and the battery 12 through a controllable normally closed switch 16. A control circuit 17 controls the switches individually at control by an operator, as indicated by the manual keys 18 and 19. However, it is also possible to provide an automatic control of the switches. This automatic control could be a remote control, as indicated by the broken arrow on top of the circuit 17. Thus it is possible to provide a battery test just by remote control.

When a check is to be done of the battery 1 the switch 15 disconnects the negative pole of the battery 11 from the bus bar 14 and connects a current source 20 between the battery and the bus bar 14. The current source is controlled by a control device 21 adapted to control the current source 20 to maintain either a desired output current or a desired output power from the battery 11. The voltage across the battery 11 is monitored at least during the check time by a voltage-measuring device 22, which also could monitor the voltage of the battery 12.

It is indicated in FIG. 2 that the voltage-measuring device 22 could send the measured data to a remote station for example if something fatal should happen to one of the batteries in the mean time between checking, or when an operator wishes to monitor the battery voltage just in case. The battery 12 could be checked in the same way as the battery 11 by connecting the same current source 20 between its negative pole and the bus bar 14. It is to be noted that the batteries 11 and 12 are checked individually and not simultaneously.

Although the invention is described with respect to exemplary embodiments it should be understood that modifications can be made without departing from the scope thereof. Accordingly, the invention should not be considered to be limited to the described embodiments, but defined only by the following claims, which are intended to embrace all equivalents thereof.

1. A method of in-circuit capacity testing of at least one stand-by electrical energy storage device (1; 11; 12) connected between two conductors (3, 4; 13, 14) in parallel with a DC supply, in turn supplied from a mains line, and also in parallel with a power consuming device (2), characterized by during a test operation for one said electrical energy storage device (1; 11; 12):
providing a controllable current source (6; 20) connected in series with the electrical energy storage device (1; 11; 12) between the two conductors (3, 4; 13, 14),
controlling the controllable current source (6; 20) to maintain either a desired output current or a desired output power from the electrical energy storage device (1; 11;12),
measuring the voltage across the electrical energy storage device (1; 11; 12), and
determining the capacity of the electrical energy storage device (1; 11; 12) in dependence on measured voltages across the electrical energy storage device.

2. The method as claimed in claim 1, characterized by choosing the controllable current source (6; 20) such that when it is adapted to drive the unloading current through the battery out on the two conductors (3, 4; 13, 14) in parallel with the DC supply (5), the current is closed through the power consuming device (2), whereby the DC supply will decrease its output current in the same extent, such that the voltage across the two connectors is constant.

3. A method of in-circuit capacity testing of at least one stand-by electrical energy storage device (1; 11; 12) connected between two conductors (3, 4; 13, 14) in parallel with a DC supply, in turn supplied from a mains line, and also in parallel with a power consuming device (2), characterized by during a test operation for one said electrical energy storage device (1; 11; 12):
providing a controllable current source (6; 20) connected in series with the electrical energy storage device (1; 11; 12) between the two conductors (3, 4; 13, 14),
controlling the controllable current source (6; 20) to maintain either a desired output current or a desired output power from the electrical energy storage device (1; 11;12),
choosing the controllable current source (6; 20) such that when it is adapted to drive the unloading current through the battery out on the two conductors (3, 4; 13, 14) in parallel with the DC supply (5), the current is closed through the power consuming device (2), whereby the DC supply will decrease its output current in the same extent, such that the voltage across the two connectors is constant.

4. The method as claimed i claim 3, characterized by
measuring the voltage across the electrical energy storage device (1; 11; 12), and
determining the capacity of the electrical energy storage device (1; 11; 12) in dependence on measured voltages across the electrical energy storage device.

5. The method as claimed in anyone of the preceding claims, characterized by controlling the controllable current source (6; 20) to maintain either a constant output current or a constant output power from the electrical energy storage device (1; 11; 12) during a test operation.

6. The method as claimed in anyone of the preceding claims, characterized by choosing the controllable current source (6) such that the voltage across it together with the voltage across the electrical energy storage device (1; 11; 12) during normal conditions without control of it is lower than the voltage across the DC supply supplied from a mains line.

7. The method as claimed in anyone of the preceding claims, characterized by having each electrical energy storage device (1; 11; 12) normally directly connected between the conductors (3, 4; 13, 14); and
connecting the controllable current source (6; 20) between one of the conductors (4, 14) and one of the poles of the electrical energy storage device (1; 11; 12) only during testing of the electrical energy storage device.

8. The method as claimed in anyone of the preceding claims, where at least two stand-by batteries are provided between the conductors (13, 14), characterized by providing the same controllable current source (20) to be connected in series with the electrical energy storage device (11; 12) among the electrical energy storage devices actually being tested.

9. The method as claimed in claim 7 or 8, characterized by controlling the connecting the controllable current source (6; 20) by remote control when a test of one said at least one electrical energy storage device (1; 11; 12) is to be tested.

10. An arrangement for in-circuit capacity testing of a stand-by electrical energy storage device (1; 11; 12) connected between two conductors (3, 4; 13, 14) in parallel with a DC supply (5), in turn supplied from a mains line, and also in parallel with a power consuming device (2), characterized in that it comprises
a controllable current source (6; 20) to be connected in series with the electrical energy storage device (1; 11; 12),
a control device (7; 21) for controlling the controllable current source (6; 20) to maintain either a desired output current or a desired output power from the electrical energy storage device (1; 11; 12), and
a voltage measuring device (8; 22) for measuring the voltage across the electrical energy storage device (1; 11; 12) at least to determine the capacity of the electrical energy storage device.

11. The arrangement as claimed in claim 10, characterized in that said control device (7; 21) is adapted to control the controllable current source (6; 20) to maintain either a constant output current or a constant output power from the electrical energy storage device (1; 11; 12).

12. The arrangement as claimed in claim 10 or 11, characterized in that the controllable current source (6) is provided such that the voltage across it together with the voltage across the electrical energy storage device (1) during normal conditions without control by the control device (7) is lower than the voltage across the DC supply (5) supplied from the mains line.

13. The arrangement as claimed in anyone of the claims 10 to 12, characterized by controllable switching connector means (15, 16) connecting each electrical energy storage device (11; 12) normally directly connected between the conductors (13, 14); and
control means (17) adapted control the switching connector means (15, 16) to connect the controllable current source (20) between one of the conductors (14) and one of the poles of the electrical energy storage device (11; 12) only during testing of the electrical energy storage device.

14. The arrangement as claimed in anyone of the claims 10 to 13, where at least two stand-by batteries are provided between the conductors (13, 14), characterized in that the same controllable current source (20) is adapted to be connected in series with the electrical energy storage device (11; 12) among the electrical energy storage devices actually being tested.

15. The arrangement as claimed in claim 13 or 14, characterized by remote control means in the control means (17) to control it to connect the controllable current source (6; 20) to the electrical energy storage device (1; 11; 12) by remote control when a test of one said at least one electrical energy storage device (1; 11; 12) is to be tested.
